(19) United States
(12) Patent Application Publication
(10) Pub. No.: US 2011/0023908 A1
(43) Pub. Date: Feb. 3, 2011

(54) METHODS AND APPARATUS FOR PROCESS ABATEMENT WITH RECOVERY AND REUSE OF ABATEMENT EFFLUENT

(75) Inventors: ANDREAS NEUBER, Stuttgart (DE); PHIL CHANDLER, Bristol (GB); CLIFFORD C. STOW, Boulder Creek, CA (US); DANIEL O. CLARK, Pleasanton, CA (US); MICHAEL KIEFER, Neuhausen (DE)

Correspondence Address: Moser IP Law Group / Applied Materials, Inc., 1030 Broad Street, Suite 203, Shrewsbury, NJ, 07702, US

(73) Assignee: APPLIED MATERIALS, INC., Santa Clara, CA (US)

(21) Appl. No.: 12/838,146

(22) Filed: Jul. 16, 2010

Related U.S. Application Data
(60) Provisional application No. 61/229,861, filed on Jul. 30, 2009.

(51) Int. Cl. B01D 53/73; B08B 7/00; H01L 21/30; B01J 19/00; B01D 53/68

(52) U.S. Cl. 134/12; 156/345.29; 134/10

(57) ABSTRACT

Methods and apparatus for recovering hydrogen fluoride (HF) are provided herein. In some embodiments, an apparatus includes a system for processing substrates, including a process chamber for processing a substrate; a fluorine generator coupled to the process chamber to provide fluorine (F₂) thereto; an abatement system coupled to the process chamber to abate fluorine-containing effluents exhausted from the process chamber and to convert at least a portion of the fluorine-containing effluents into hydrogen fluoride (HF); an HF recovery system configured to at least one of collect, purify, or concentrate the HF converted by the abatement system; and a conduit for providing the recovered hydrogen fluoride (HF) to the fluorine generator or another application in the manufacturing process.

### CROSS-REFERENCE TO RELATED APPLICATIONS

This application claims benefit of U.S. provisional patent application Ser. No. 61/229,861, filed Jul. 30, 2009, which is herein incorporated by reference in its entirety.

### FIELD

Embodiments of the present invention generally relates to apparatus for processing substrates.

### BACKGROUND

In semiconductor, flat panel, photovoltaic, nanomanufacturing, organic light emitting diode (OLED), and other silicon or thin film processing systems, components of the system require cleaning after a period of use. For example, components can include a process chamber, an exhaust conduit, or any component where process gases or process materials may deposit during use. The system components, such as the process chamber and exhaust conduit, can be cleaned using, for example, a fluorine-containing gas and/or a plasma formed from the fluorine-containing gas such as NF₃ or fluorine (F₂). A reactive fluorine species of the plasma can include singlet fluorine (F), or fluorine radical. The fluorine-containing gas can be generated on site or locally using a fluorine generator. Typically, a point of use fluorine generator can use hydrogen fluoride (HF) as a fluorine source from which to generate fluorine (F₂). Once, the fluorine-containing gas and/or fluorine reactive species acts to remove contaminants or the like from, for example, a process chamber, the fluorine-containing gas and/or byproducts formed by a reaction therefrom, such as silicon tetrafluoride (SiF₄), are exhausted from the chamber. Unfortunately, these exhausted effluents are often toxic, corrosive, or present global warming potential that requires further treatment and/or disposal. Further, HF used to fuel the fluorine generator is also toxic and requires appropriate handling, for example, during re-fueling of the fluorine generator.

### SUMMARY

Methods and apparatus for recovering hydrogen fluoride (HF) are provided herein. In some embodiments, an apparatus includes a system for processing substrates, including a process chamber for processing a substrate; a fluorine generator coupled to the process chamber to provide fluorine (F₂) thereto; an abatement system coupled to the process chamber to abate fluorine-containing effluents exhausted from the process chamber and to convert at least a portion of the fluorine-containing effluents into hydrogen fluoride (HF); an HF recovery system configured to at least one of collect, purify, or concentrate the HF converted by the abatement system; and a conduit for providing the recovered hydrogen fluoride (HF) to at least one of the fluorine generator or a second process chamber coupled thereto.

In some embodiments, a method for recovering hydrogen fluoride (HF), comprises generating fluorine (F₂) using a fluorine generator; directing the fluorine into a process chamber; utilizing a reactive fluorine species formed from the fluorine (F₂) in a process performed in the process chamber; converting fluorine-containing effluents into hydrogen fluoride (HF) and a byproduct species within an abatement system coupled to the process chamber; recovering the HF by separating the HF from the byproduct species in an HF recovery system coupled to the abatement system; and providing recovered HF to the fluorine generator to fuel the generation of fluorine (F₂). In some embodiments, the method further includes providing the recovered HF to a second process chamber. In some embodiments, the process performed in the process chamber is a cleaning process. In some embodiments, the process performed in the process chamber is an etching process. In some embodiments, the method further includes providing the reactive fluorine species to clean an exhaust conduit coupled to the process chamber. Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic of a processing system in accordance with some embodiments of the present invention.

FIG. 1A depicts a variant of the processing system of FIG. 1 in accordance with some embodiments of the present invention.

FIG. 2 depicts a detailed view of abatement system and HF recovery system of the processing system of FIG. 1 in accordance with some embodiments of the present invention.

FIG. 3 depicts a flow chart for a method of recovering HF in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for recovering and reusing hydrogen fluoride (HF) abatement effluent are provided herein. The inventive apparatus includes a processing system that advantageously provides a full chemical lifecycle system for chamber cleaning, abatement and recovery of at least a portion of the HF, separation purification and concentration of at least a portion of the HF, conversion of at least a portion of the purified aqueous HF to anhydrous HF or a fluorinated compound capable of being a source material for formation of fluorine (F₂) to be used as a chamber cleaning gas. The inventive methods and apparatus advantageously recover and reuse a substantial portion of the initial F₂ used as the cleaning gas. The inventive apparatus reduces the need for purchasing, transporting and processing large volumes of toxic materials and effluents (e.g., fluorine-containing effluents) and handling toxic raw materials (e.g., HF) used to fuel the fluorine generator. The inventive methods and apparatus may further include utilization of the recovered HF for other processes, for example, such as cleaning or etch process in either the same and/or a different process chamber. Further, waste materials, such as hydrogen (H₂) generated from the electrolytic formation of F₂ from HF can be advantageously utilized as, for example, fuel for an abatement process.

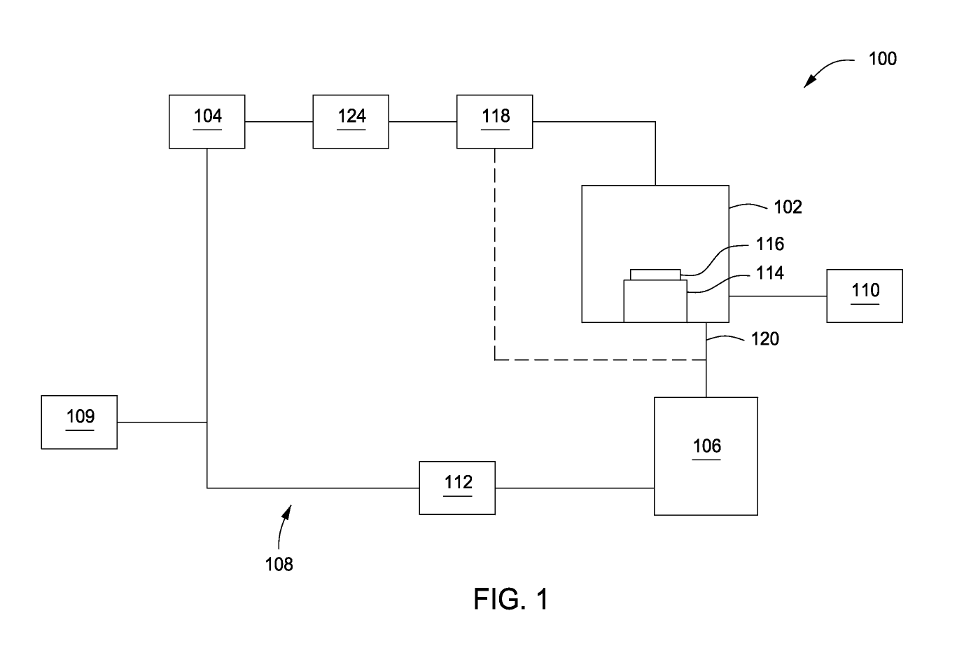

An exemplary semiconductor processing system 100 is schematically illustrated in FIG. 1. The semiconductor processing system 100 includes a process chamber 102 for processing a substrate and having a fluorine generator 104 coupled thereto. Optionally, the fluorine generator 104 may be coupled to the process chamber 102 via a remote plasma system 118 to supplying fluorine radicals or the like for cleaning the process chamber or etching a substrate as discussed below. The fluorine generator 104 provides fluorine (F₂) to the process chamber 102, and, optionally, other components as discussed below, for example, for cleaning the process chamber 102 and/or other components. An abatement system 106 is coupled to the process chamber 102 to abate fluorine-containing effluent exhausted from the process chamber 102. The abatement system 106 converts at least a portion of the fluorine-containing effluent into hydrogen fluoride (HF).

An HF recovery apparatus 112 is provided to recover the HF produced by the abatement system 106. The HF recovery apparatus 112 is configured to at least one of collect, purify, or concentrate the HF produced by the abatement system 106. The HF recovery apparatus 112 may be integral with the abatement system 106, partially integrated with the abatement system 106, or separate from the abatement system 106. In the embodiment depicted in FIG. 1, the HF recovery apparatus 112 is disposed along a conduit 108 coupling the abatement system 106 and the fluorine generator 104.

The conduit 108 couples the abatement system 106 to the fluorine generator 104 and is utilized for providing the recovered hydrogen fluoride (HF) to the fluorine generator 104. The recovered HF may be utilized by the fluorine generator 104 to fuel the generation of fluorine (F₂) to be utilized in the process chamber 102. A controller 110 may be coupled to the process chamber 102, the fluorine generator 104, and the abatement system 106 for controlling the respective operations thereof. Alternatively, the system 100 need not be limited to a closed-looped system, for example, and optionally, the conduit 108 may further be coupled to a second process chamber 109 for providing the recovered HF thereto. For example, the recovered HF may be utilized in a cleaning or etching process in the second process chamber 109. In some embodiments, (not shown) the conduit 108 may be coupled to the second process chamber 109 (and not the fluorine generator 104) to provide the recovered HF to the second process chamber 109.

The semiconductor processing system 100 described above is merely exemplary and other processing systems are possible, for example, a processing system having two or more process chambers coupled to the same abatement system, a process chamber coupled to multiple abatement systems, where each abatement system may be configured for processing a specific effluent, a fluorine generator coupled to two or more process chambers and fueled by recovered HF from one or more abatement systems and/or one or more HF recovery systems, or the like.

The process chamber 102 may be any suitable chamber for processing a substrate. For example, the process chamber 102 may be configured for performing gas phase or liquid phase processes. Non-limiting examples of such gas phase processes may include chemical vapor deposition, physical vapor deposition, dry chemical etching, plasma etching, plasma oxidation, plasma nitridation, rapid thermal oxidation, epitaxial deposition, and the like. Non-limiting examples of such liquid phase processes may include wet chemical etching, physical liquid deposition and the like. An exemplary process chamber 102 may, for example, include a substrate support 114 having a substrate 116 disposed there on, a gas panel for providing one or more process gases (not shown), and a means of distributing the process gases in the process chamber, for example, a showerhead or nozzle (not shown). The chamber may be configured for providing a plasma therein, which may be formed in any manner, such as by capacitive coupling, inductive coupling, or the like. The plasma may be formed in-situ (e.g., within the process chamber 102), or formed remotely and directed into the process chamber 102. The process chamber 102 may include one or more heating lamps or other energy source, for example, when configured for rapid thermal processes (RTP), epitaxial deposition processes, chemical vapor deposition processes. or the like.

A substrate 116 processed in the process chamber 102 may be any suitable substrate processed in a semiconductor process chamber, or other suitable process chamber such as those configured for flat panel, photovoltaic, nanomanufacturing, organic light emitting diode (OLED), and other silicon or thin film processing. The substrate 116 may be any suitable material to be processed, such as a crystalline silicon (e.g., Si<100> or Si<111>), a silicon oxide, a strained silicon, a silicon germanium, a doped or undoped polysilicon, a doped or undoped silicon wafers, patterned or non-patterned wafers, silicon on insulator (SOI), carbon doped silicon oxides, silicon nitride, doped silicon, germanium, gallium arsenide, glass, sapphire, a display substrate (such as a liquid crystal display (LCD), a plasma display, an electro luminescence (EL) lamp display, or the like), a solar cell array substrate, a light emitting diode (LED) substrate, or the like. The substrate 116 may have various dimensions, such as 200 mm or 300 mm diameter wafers, as well as rectangular or square panels, where the rectangular or square panels can range in size from small to large depending on the type of application for which the panels are being used. The frontside surface of the substrate 116 may be hydrophilic, hydrophobic, or a combination thereof. The frontside surface may be patterned, or having one or more patterned layers, such as a photomask, disposed thereon.

The process chamber 102 may be configured, for example, to deposit a layer of material on the substrate 116, or alternatively, to etch the substrate 116 or a material deposited on the substrate 116. Such layers deposited on the substrate may include layers for use in a semiconductor device, for example, a metal oxide semiconductor field effects transistor (MOSFET) or a flash memory device. Such layers may include silicon-containing layers, such as polysilicon, silicon nitride, silicon oxide, silicon oxynitride, metal silicide, or alternatively, metal containing layers, such as copper, nickel, gold, or tin containing layers, or metal oxide layers, for example hafnium oxide. Other deposited layers may include, for example, sacrificial layers such as etch stop layers, photoresist layers, hardmask layers, and the like.

The process chamber 102 may use any suitable process gas and/or process gas mixture, for example, to form a layer atop the substrate 116, to remove material from the substrate 116, or to otherwise react with material layers exposed upon the substrate, or the like. Such process gases may include silicon-containing gases, such as silane (SiH₄), dichlorosilane (Cl₂SiH₂), or the like; and/or metal-containing gases, such as metalorganics, metal halides or the like. Other process gases may include inert gases, such as helium (He), argon (Ar), nitrogen (N₂), or the like; and/or reactive gases, such as halogen-containing gases, oxygen (O₂), hydrogen fluoride (HF), hydrogen chloride (HCl), fluorine (F₂), chlorine (Cl₂) or the like. Other process gases may include dopants or hydrides such as AsH₃ or PH₃.

In some embodiments, the fluorine generator 104 may include an electrochemical cell having a plurality of electrodes, for example, two electrodes disposed in a bath of electrochemical solution. The electrodes may be separated by a semi-permeable membrane, for example, such a NAFION® (a sulfonated tetrafluoroethylene based fluoropolymer-copolymer) or polytetrafluoroethylene (PTFE) membrane, or the like. The electrodes may, for example, comprise carbon, such as graphite electrodes or the like. The electrochemical solution may comprise hydrogen fluoride (HF), water (H2O), and one or more electrolytes, for example, sodium chloride (NaCl), potassium chloride (KCl), or the like. In operation, a DC power supply provides a potential between the plurality of electrodes causing the formation of hydrogen (H₂) proximate one electrode and the formation of fluorine (F₂) at the other electrode. The semi-permeable membrane can function to prevent the gas phase interaction of, for example, H₂ and F₂ which are formed at the opposing electrodes above the electrolyte. The tear or leak in the membrane could result in a reaction between interaction of H₂ and F₂. This could, for example, result in a chemical reaction would release a significant amount of energy in which energy is released thus presenting a safety hazard during operation. Typically, H₂ generated by the fluorine generator can be vented to atmosphere. In some embodiments, (not shown) H₂ generated by the fluorine generator can be polished and used for a process performed in the chamber 102 or another chamber, and/or used as a fuel in an abatement system, such as in a hydrogenation reactor 202 of an abatement system 106 described below. Alternatively, the fluorine generator 104 may include one or more devices (discussed below) for converted HF to CaF₂, where F₂ may be evolved by heating CaF₂.

In some embodiments, the fluorine generator 104 may be coupled to the process chamber via a remote plasma source 118 (illustrated in FIG. 1). The remote plasma source 118 may be any suitable remote plasma source for generating a plasma remotely from a process chamber. In operation, fluorine (F₂) generated by the fluorine generator 104 is converted into a reactive species, such as fluorine ions, fluorine radicals or the like, by the remote plasma source 118 and is subsequently provided to clean the chamber or etch substrates in the process chamber 102.

Optionally, the remote plasma source 118 may be further coupled to an exhaust conduit 120 disposed between the process chamber 102 and the abatement system 106. The remote plasma source 118 may provide reactive species to the exhaust conduit 120 to, for example, react with exhausting effluent or to react with materials deposited on the walls of the exhaust conduit.

The exhaust conduit 120 may include, or may be coupled to, a pumping system (not shown) that moves effluent from the process chamber 102 and into the abatement system 106. The pumping system may be disposed in and/or coupled to the exhaust conduit 120 for maintaining chamber pressure, evacuating effluent from the chamber, or the like. The pumping system may include, for example, a turbomolecular pump, a blower, and a mechanical pump.

Alternatively, in some embodiments, the fluorine generator 104 may be coupled to the process chamber 102 (as illustrated in FIG. 1A) to flow the fluorine (F₂) generated by the generator 104 to the process chamber 102. A plasma source 122 may be coupled to the process chamber 102 to form a plasma from the fluorine (F₂) and convert the fluorine (F₂) in situ into a reactive species such as fluorine ions or fluorine radicals. The plasma source 122 may be any suitable plasma source to form a plasma in the process chamber. For example, the plasma source may be configured to provide an inductively coupled plasma, a capacitively coupled plasma, or the like. Optionally (not shown), the fluorine generator may be coupled to the both the process chamber 102 and the remote plasma source 118. For example, during an etch recipe, steps may be performed using one or more of a remote plasma, an in situ chamber plasma, or a thermal process, such as a cleaning process.

Returning to FIG. 1, any process gas or liquid, process gas or liquid mixture, substrate, deposited materials, removed materials, or combinations thereof may comprise and/or combine to form effluent that is exhausted from the process chamber 102. The effluent may include un-reacted or excess portions of a process gas or chemical agent used for processing the substrate or cleaning the chamber and/or chamber components such as re-usable process kits or process kit shields. The effluent generated in these processes can include different compositions of flammable and/or corrosive compounds, sub-micron sized process residue particulates and gas phase nucleated materials, and other hazardous or environmentally polluting compounds. For example, the effluent may contain different compositions of halogen containing gases, perfluorocompounds (PFCs), chlorfluorocompounds (CFCs), hazardous air products (HAPs), volatile organic compounds (VOCs), and the like. In some embodiments, the effluents are fluorine-containing effluents, for example, including reactive species generated by the fluorine generator 104 and plasma source 118 (or 122), and/or compounds formed from reactions with the reactive species and materials present in the process chamber 102. Exemplary fluorine-containing effluents include fluorine (F₂), singlet atomic fluorine (F), fluorine radicals (F*), silicon tetrafluoride (SiF₄), nitrogen trifluoride (NF₃), carbon tetrafluoride (CF₄), oxyfluorosilicates, silicon fluorohydrides (SiFₓH), perfluorocompounds (PFCs), or combinations thereof.

Effluent from the process chamber (exhausted via the exhaust conduit 120) are directed to the abatement system 106. The abatement system 106 operates to convert at least a portion of the fluorine-containing effluents into hydrogen fluoride (HF). The abatement system 106 may also be utilized to process other types of effluents from the process chamber 102 and/or other process chambers coupled to the abatement system 106. In some embodiments, the abatement system 106 can utilize the effluent H₂ reagent from the F₂ generator 104, as a fuel and to react the effluent to form HF. The fuel and reagent value of the H₂ from the fluorine generator 104 may have many other alternate uses within the factory.

The abatement system 106 may be any suitable abatement system for receiving and processing the effluent from a semiconductor process chamber, for example, the process chamber 102. The abatement system 106 may be employed to abate a single process chamber or tool, or multiple process chambers and/or tools. The abatement system 106 may use, for example, thermal, wet scrubbing, dry scrubbing, catalytic, plasma and/or similar means for the treatment of the effluent, as well as processes for converting the effluent to less toxic forms, or other forms such as HF to be used as a reagent in the fluorine generator 104. The abatement system 106 may further include multiple abatement systems (not shown) for processing particular types of effluent from the process chamber 102. For example, one of the multiple abatement systems could be specifically tasked for converting fluorine-containing effluents to hydrogen fluoride (HF), and a second abatement system could be used for abating the effluent from, for example, a deposition process.

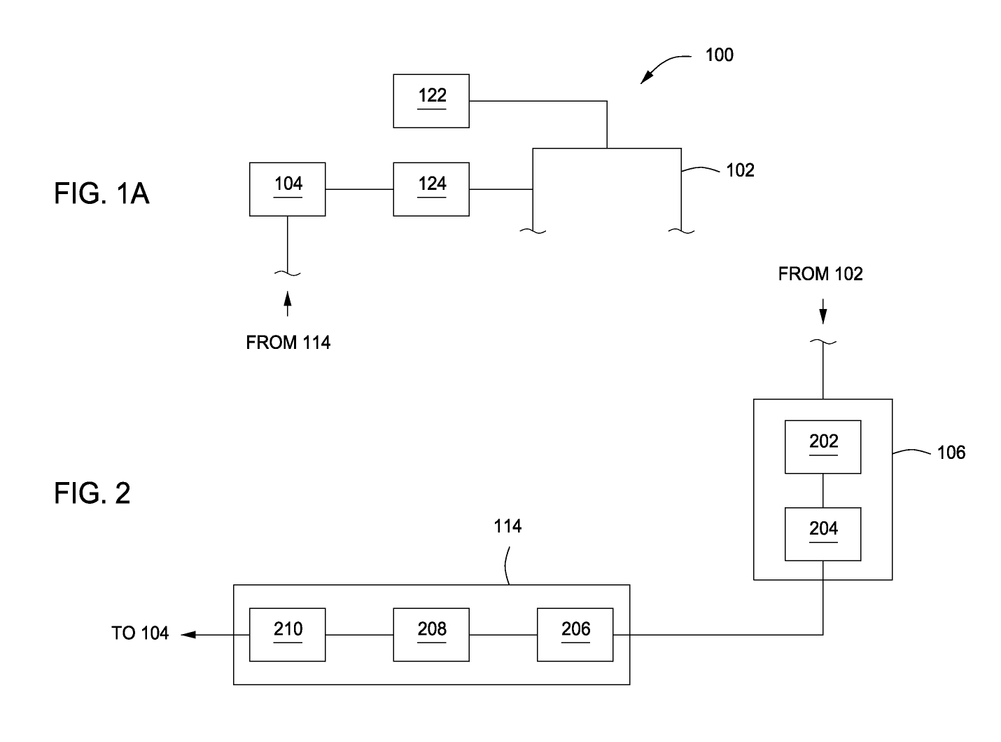

The abatement system 106, for example, may include one or more of a hydrogenation reactor 202, a thermal reactor 204 (i.e., combustion reactor), or the like (illustrated in FIG. 2). The example in FIG. 2 shows two abatement devices (e.g., the hydrogen reactor 202 and the thermal reactor 204) in series. In some embodiments (not shown), the two abatement devices (for example, the hydrogenation reactor and the thermal reactor) could be disposed in parallel with switching valves provided to divert the fluorine-containing effluents (e.g., F₂ and/or HF from a chamber clean process) to one abatement device (such as the hydrogenation reactor 202) and the process (e.g., deposition) effluent to a second abatement device (e.g., the thermal reactor 204). In some embodiments, the abatement system includes either a thermal reactor or a hydrogenation reactor converting at least a portion of the fluorine-containing effluents into hydrogen fluoride (HF) and byproduct species. Byproduct species may include, for example, those portions of the fluorine-containing effluents not converted into HF. Byproduct species may include solid materials, such as silicon dioxide (SiO₂) particulates, or water-soluble or reactive materials, such as dissolved silica species, HF, HCl, NF₃, CF₄, SiH₄, H₂, CO, CO₂, trimethylborate (TMB), tetraethoxysilane (TEOS), PH₃, CH₄, phosphorous oxides, or boron oxides.

A portion of the fluorine-containing effluent exhausted from a chamber may include, for example, fluorine (F₂). The fluorine-containing effluent may be initially injected into hydrogenation reactor 202 which can be used to convert halogens (e.g., F₂) into hydrogen-containing gases (e.g., HF). The hydrogenation reactor 202 is not limited to processing fluorine-containing effluent.

Alternatively or in combination with the hydrogenation reactor 202, the abatement system 106 may further comprise the thermal reactor 204. For example, the thermal reactor 204 may be utilized to process a portion of the fluorine-containing effluents, for example, such as effluents comprising silicon and fluorine, such as silicon tetrafluoride (SiF₄). For example, the fluorine-containing effluent can be injected into the thermal reactor 204 to convert, for example, a fluorine-containing effluent (e.g., SiF₄) into a hydrogen-containing gas (e.g., HF) and an oxygen-containing material (e.g., SiO₂). An exemplary thermal reactor may, for example burn effluent, such as SiF₄ in an atmosphere of an oxygen-containing gas such as water (H₂O) vapor to form hydrogen fluoride (HF) and silicon dioxide (SiO₂) which can be separated by, for example, a scrubber as discussed below.

Once at least a portion of the fluorine-containing effluent has been converted to HF, the HF and the byproducts (e.g., SiO₂) formed therewith are flowed to the HF recovery system 112. At the HF recovery system 112 (illustrated in detail in FIG. 2), the recovered HF is at least one of collected, purified, or concentrated prior to being flowed to the fluorine generator 104 via the conduit 108. As noted above, the HF recovery system 112 may be integral with, partially integrated with, or completely separate from the abatement system 106 or multiple abatement systems.

In some embodiments, the HF recovery system 112 may include one or more of a scrubber 206, a vacuum distillation apparatus 208, or an apparatus 210 for concentrating the recovered HF. In some embodiments, the apparatus 210 may be suitable for converting 30% concentration HF (recovered from a combination of scrubbing and distillation) to anhydrous HF. The recovered HF may be collect and/or purified by either or both of the scrubber 206 and the vacuum distillation apparatus 208. The recovered HF may be converted as discussed above by the apparatus 210. The HF recovery system 112 is exemplary, and other variants of the system are possible. For example, in some embodiments, the scrubber 206 may be part of the abatement system 106.

In operation, for example, the recovered HF and byproduct species (e.g., SiO₂) may enter the HF recovery system 112 and initially be collected and removed by the scrubber 206. The scrubber 206 may be any suitable scrubber utilized with abatement processes, such as a hydrocyclone, a liquid particulate scrubber, or a liquid scrubber (e.g., a water scrubber) or the like. For example, in water scrubbing, the recovered HF and byproduct species are brought into contact with water, using methods, such as bubbling the recovered HF and byproduct species through a water spray or the like to remove water soluble species. Some materials (e.g., recovered HF), which are soluble in water may be collected by the scrubber. Other materials, for example, byproduct species such as SiO₂, which are insoluble in water may be removed by the scrubber 206. Other byproduct species which are water soluble, if any, may also be collected by the scrubber in addition to the recovered HF. In one embodiment, the scrubber is a hydrocyclone.

After scrubbing, the water soluble materials, e.g., the recovered HF and any additional water soluble byproduct species, may be flowed from the scrubber 206 to the vacuum distillation apparatus 208. The vacuum distillation apparatus 208 may include a distillation column or a vacuum distillation column for distilling the recovered HF from the water soluble byproduct species. For example, the distillation column may be kept at a pressure below atmospheric pressure, such that the most volatile chemical species (e.g., those species with the lowest boiling points) will evaporate first. Accordingly, hydrogen fluoride (HF), having a boiling point of about 20 degrees Celsius, can be separated from the remaining water soluble byproduct species having higher boiling points. In one embodiment, the vacuum distillation apparatus 208 recovers about 30% concentration HF from the water soluble materials flowed from the scrubber 206.

The materials recovered from the vacuum distillation apparatus 208 include approximately 30% concentration HF. In some embodiments, the materials recovered may range from about 1% to about 35% concentration HF. However, the concentration of HF in water may not be suitable for use in some embodiments of the fluorine generator 104. For example, Electrochemical F₂ generator cells, such as those cells that may be used in the fluorine generator 104, typically require a highly concentrated anhydrous HF feed. Accordingly, the apparatus 210 can be used to convert about 30% (or any percent concentration HF within the ranges discussed above) concentration HF to anhydrous HF to be used by the cells of the fluorine generator 104. For example, in some embodiments, the device 210 may be a furnace or a another device as discussed below, where the 30% concentration HF is converted to anhydrous HF and the anhydrous HF is flowed in a controlled fashion to the fluorine generator 104 via the conduit 108.

Alternatively, in some embodiments, the HF recovered from the vacuum distillation apparatus 208 may be converted to calcium fluoride (CaF₂), as high surface area solid pellets, beads, or the like, and used to form F₂. CaF₂ may also be known as fluorite or fluorspar. For example, to convert the about 30% concentration HF to CaF₂, the fluorine generator 104 may be a heated fluidized bed reactor or a hot rotary calciner that spray dries the HF onto high surface area calcium carbonate (CaCO₃) to form CaF₂, carbon dioxide (CO₂), and H₂O. In some embodiments, the CaCO₃, which may be a high surface area pellet, bead, or the like, may be heated to form the CaF₂. Subsequently, high surface area pellets of the formed CaF₂ may be dried, such as by a dryer 124 as discussed below, and then fed to a controlled high temperature furnace (which can be part of the fluorine generator 104) to control the rate of F₂ evolved from the CaF₂. The high surface Ca carrier from which the recovered F₂ is evolved is recycled locally or off site and reformed into high surface area CaCO₃ for subsequent CaF₂ generation processes.

Alternatively, a liquid fluidized bed comprising CaF2 crystallizers may be used to recover fluorides, such as HF and any other water-soluble fluorine-containing effluents that survive the scrubber 206. For example, the scrubbed effluents may be passed through the fluidized bed where any one or more of the fluorine-containing effluents interact with the crystallizers to form CaF₂. The fluidized bed may include a silicon sand substrate or the like. In some embodiments, the amount of fluorides recovered from the fluorine-containing effluents may range from about 80% to about 97%. For example, and to generate HF from the CaF₂ (such as for use in a fluorine generator having an electrochemical cell), the CaF₂ may be reacted with sulfuric acid (H₂SO₄) to form gaseous HF and solid calcium sulfate (CaSO₄). In some embodiments, the gaseous HF may be purified, for example, to remove water or the like, prior to flowing to an electrochemical cell to generate F₂, or in some embodiments, F₂ and H₂. Further, the above-mentioned sulfuric acid conversion to HF may also be utilized with CaF2 formed from CaCO₃ as well.

Alternatively, the fluorine generator 104 may be a reaction vessel that reacts 30% concentration HF with a calcium—containing precursor to form high surface area CaF₂, which may be subsequently dried and heated to evolve F₂ which can be fed to the remote plasma source 118 as discussed above.

Alternatively, the recovered materials from the vacuum distillation apparatus 208, for example, HF ranging in concentration from about 1 to about 35% may be collected and utilized in other processes, processing systems, or the like, such as other semiconductor process chambers or process chambers configured for solar technologies, or wet chemical processes, or any suitable process or process chamber where HF ranging in concentration from about 1 to about 35% may be useful.

The apparatus 210 for concentrating the recovered HF may include for example, one or more of a membrane, electrically assisted membrane, ion exchange membrane, or freezing apparatus for concentrating the recovered HF.

Returning to FIG. 1, the controller 110 may coupled to the process chamber 102 for controlling the operation thereof. The controller 110 may be the controller for operating the system 100, or portions thereof, or it may be a separate controller. The controller 110 generally comprises a central processing unit (CPU), a memory, and support circuits for the CPU (not shown). The controller 110 may control the process chamber 102 directly (e.g. via a digital controller card), or via computers (or controllers) associated with particular process chamber and/or the support system components. The controller 110 may be one of any form of general-purpose computer processor that can be used in an industrial setting for controlling various chambers and sub-processors. The memory, or computer-readable medium of the CPU may be one or more of readily available memory such as random access memory (RAM), read only memory (ROM), floppy disk, hard disk, flash, or any other form of digital storage, local or remote. For example, instructions for performing the methods disclosed herein may be stored in the memory of the CPU, and when executed, perform the method. The support circuits are coupled to the CPU for supporting the processor in a conventional manner. These circuits may include cache, power supplies, clock circuits, input/output circuitry and subsystems, and the like.

In some embodiments, a dryer may be provided to remove water (H₂O) from at least one of the (F₂). For example, a dryer 124 may be coupled to the fluorine generator 104 (as illustrated in FIGS. 1 and 1A). The dryer 124 may be an emulsive dryer, a pressure swing adsorption (PSA) bed, a set of molecular sieve dryer, or mole sieve swing drying beds (for example, one being regenerated while the other one dries F₂ generated by the fluorine generator), or the like. For example, the dryer 124 may be configured to dry wet fluorine (F₂), e.g., after the fluorine generator 104 has converted HF to F₂, or CaF₂ to F₂ (illustrated in FIGS. 1 and 1A). Alternatively or in combination, the dryer 124 may be configured to dry wet HF prior to the HF entered the fluorine generator 104 (not shown).

Optionally, the system 100 may have alternative configurations to those illustrated in FIGS. 1 and 1A. For example, in some embodiments the fluorine generator and the vacuum distillation apparatus may be disposed adjacent to the process chamber 102 as illustrated in FIGS. 1 and 1A. Alternatively, in some embodiments, the fluorine generator and vacuum distillation apparatus may be disposed in a location separate from, or remote from, the location of the process chamber 102. For example, a separate location may be, in another room, or external to the fabrication line, such as in a separate building, outside, or the like. In some embodiments, the fluorine generator, vacuum distillation apparatus, CaF2, or CaCO3 processing may be located remotely from the process chamber 102, or may be disposed in a suitable proof housing, for example, for safety concerns. For example, safety concerns may include a tear in the membrane of the fluorine generator which could lead to an explosion or similar event. Additional alternatives of the system 100 include the abatement system 106 and HF recovery system 112 integrated as a single integrated system.

The system 100 as described above is advantageous for several reasons. For example, the close loop configuration provides a reduced greenhouse gas emissions compared with typical use of PFCs for chamber cleans. Further, it advantageously allows for minimal storage of F₂ on site by generating F₂ as needed/consumed. The F₂ can be generated relatively close proximity to the chamber minimizing the volume of F₂ gas within the system. This system 100 further minimizes the need to transport large quantities of HF or NF₃ (or other PFCs or greenhouse gases) on roads or shipping lanes. Further, the system 100 minimizes the amount of fluoride (CaF₂) waste typically generated by single pass chamber clean technologies. The system 100 operates at low pressure (e.g., about 20 psi) and, coupled with a generally lower system wide volume due to the closed loop configuration, advantageously decreases the potential for a leak or break in, for example, chamber components such as conduits which supply process gases or exhaust effluents. Further, the fluorine generator may further generate waste hydrogen (H₂) during the electrolytic formation of F₂ from HF that can be recycled and used for fuel value in local abatement equipment or glass plant manufacturing.

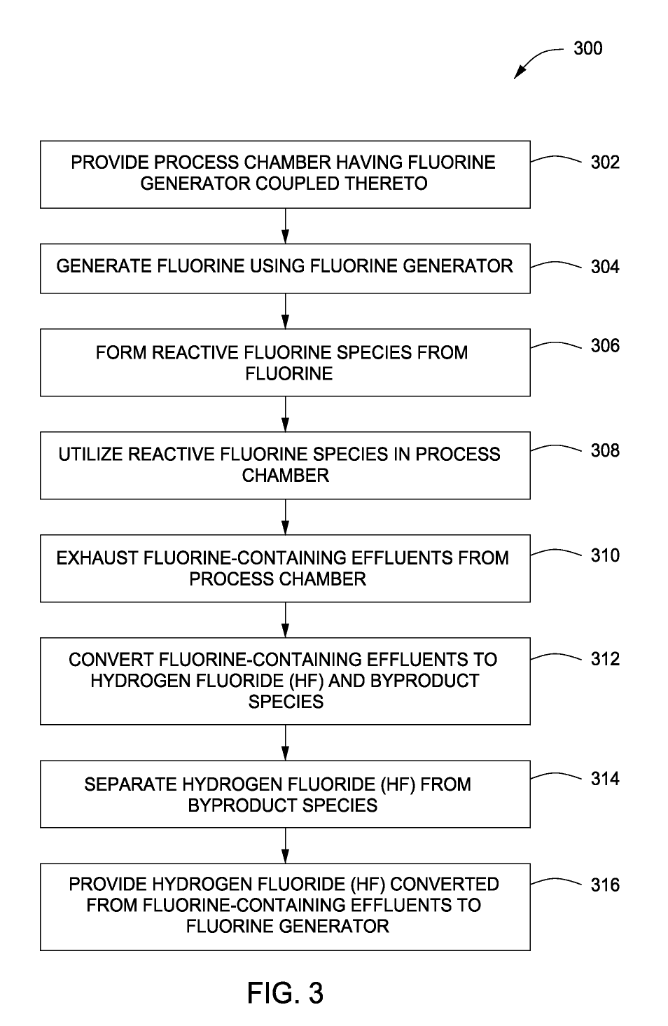

FIG. 3 depicts a flow chart for a method of recovering HF in accordance with some embodiments of the present invention. For example, the method may be part of a chamber cleaning process performed when the chamber is idle (e.g., not processing substrates). The method 100 is described below with respect to FIG. 1, however, the method may be utilized with any embodiments of the system 100 as discussed above.

The method begins at 302 by providing the process chamber 100 having the fluorine generator 104 coupled thereto. The process chamber 102 may be in an idle mode and ready for a cleaning process, or in an active mode to etch a substrate. The substrate 116 may be present for the purposes of protecting the substrate support 114 or to be etched, or alternatively, no substrate may be present.

At 304, the fluorine generator 104 generates fluorine (F₂) from the electrolysis of HF or from the heating of CaF₂. The fluorine (F₂) may be dried by the dryer 124 prior to entering the remote plasma source 118. Further, and optionally, during a first cycle of F₂ flow in the process chamber, the F₂ may be provided by a source (not shown) independent of the fluorine generator 104, such as a fluorine gas source coupled to a gas panel, or the like. Alternatively, HF may be provided to the fluorine generator 104 to begin the first cycle in the process chamber. For example, the HF may be provided from an HF source, or alternatively may be recovered HF from another process system.

At 306, a reactive fluorine species is formed from the fluorine (F₂) by the remote plasma source 118. The reactive fluorine species may include, for example, singlet fluorine (F), fluorine ions, fluorine radicals, or the like. Alternatively, the F₂ may be flowed directly to the chamber 102 and a plasma may be formed in the chamber 102 by the plasma source 122. Alternatively, the F₂ may be flowed directly to the chamber 102 and no plasma may be formed, for example, during a thermal clean or similar process.

At 308, the reactive fluorine species are utilized in the process chamber 102, for example, as part of a chamber cleaning process. The reactive fluorine species may react with contaminants present in the process chamber, such as those formed from process gases, substrate materials or the like. The contaminants are converted into a fluorine-containing effluent, which is exhausted from the process chamber at the exhaust conduit 120. Alternatively, or in combination with, the reactive fluorine species may be directly flowed to the exhaust conduit 120 from the remote plasma source 118 to convert contaminants present in the exhaust conduit 120 into fluorine-containing effluents.

At 310, the fluorine-containing effluents are exhausted from the process chamber 102 and flowed to the abatement system 106.

At 312, the fluorine-containing effluents are converted into HF and byproduct species, for example, such as insoluble and soluble byproduct species by either or both of a hydrogenation process or thermal combustion.

At 314, the HF and byproduct species are separated using the HF recovery system 112. For example, the HF and water soluble byproducts are separated from the insoluble byproducts by the scrubber 206 and the HF is separated by the water soluble byproducts by the vacuum distillation apparatus 208.

At 316, the recovered HF is provided to the fluorine generator, where F₂ is generated from the recovered HF and provided to remote plasma source 118 (or directly to the process chamber 102). As discussed above, in some embodiments, the recovered HF is converted to anhydrous HF in the HF recovery system and is provided to one or more electrochemical cells of the fluorine generator 104, where the fluorine generator 104 generates F₂ to be fed to the remote plasma source 118. Alternatively, in some embodiments and also discussed above, the recovered HF is converted to CaF₂ and heated to evolve F₂ which can be fed to the remote plasma source 118 (or directly to the process chamber 102). After the recovered HF is converted to one of anhydrous HF or CaF₂, the method 300 may generally continue in a cycle until processing is complete. For example, the method 300 may be repeated for one or more cycles, for example, to sufficiently clean the process chamber 102 of contaminants, or alternatively, may be repeated until an endpoint in the cleaning process has been reached. For example, an endpoint may include the point at which the exhausted effluents essentially include only fluorine (F₂), fluorine ions, fluorine radicals, or combinations thereof. Alternatively, or in combination with, the recovered HF may be provided to the second process chamber 109 as discussed above. For example, the recovered HF may be utilized in a process, such as cleaning, etching, or the like. Further, materials such as Ca, CaSO4, H2SO4, and other materials discussed above for recovering fluorides may be recycled and reused. Additionally, thermal energy generated at one or more stages of the recovery process may be utilized, for example, in other stages of the recovery process requiring heat, such as drying, pre-heating, vacuum distillation, or the like.

Thus, methods and apparatus for recovering and reusing hydrogen fluoride (HF) abatement effluent have been provided herein. The inventive apparatus includes a processing system that advantageously provides a closed-loop system for abating fluorine-containing effluent, converting at least some of the fluorine-containing effluent to HF, converting the recovered HF to one of anhydrous HF to fuel an F₂ generator or CaF₂ which can be heated to evolve F₂, and utilizing the F₂ in an remote plasma source to generate reactive species to clean chambers and or etch substrates. The inventive apparatus reduces the need for single pass processing of high global warming or toxic effluent (e.g., fluorine-containing effluents) and handling toxic raw materials (e.g., HF) used to fuel the fluorine generator.

While the foregoing is directed to embodiments of the present invention, other and further embodiments of the invention may be devised without departing from the basic scope thereof.

1. A system for processing substrates, comprising:
a process chamber for processing a substrate;
a fluorine generator coupled to the process chamber to provide fluorine (F₂) thereto;
an abatement system coupled to the process chamber to abate fluorine-containing effluent exhausted from the process chamber and convert at least a portion of the fluorine-containing effluent into hydrogen fluoride (HF);
an HF recovery system to at least one of collect, purify and concentrate the HF produced by the abatement system; and
a conduit for providing the recovered hydrogen fluoride (HF) to at least one of the fluorine generator or a second process system coupled thereto.

2. The apparatus of claim 1, further comprising:
a plasma source coupled to the process chamber, wherein the plasma source converts fluorine (F₂) generated by the fluorine generator into a reactive fluorine species.

3. The apparatus of claim 2, wherein the plasma source is further coupled to an exhaust conduit coupling the process chamber to the abatement system to provide the reactive fluorine species to the exhaust conduit.

4. The apparatus of claim 1, wherein the abatement system further comprises:
at least one of a thermal combustion apparatus or a hydrogen injection apparatus for converting at least a portion of the fluorine-containing effluents into hydrogen fluoride (HF) and byproduct species.

5. The apparatus of claim 4, wherein the hydrogen injection apparatus provides at least one of hydrogen radicals or hydrogen and oxygen-containing reactive species to convert at least a portion of the fluorine-containing effluents into hydrogen fluoride (HF) and byproduct species.

6. The apparatus of claim 4, wherein the HF recovery system further comprises:
a scrubber for separating the hydrogen fluoride (HF) from at least a portion of the byproduct species by solubilizing the hydrogen fluoride (HF).

7. The apparatus of claim 6, wherein the HF recovery system further comprises:
a vacuum distillation apparatus for separating the solubilized hydrogen fluoride (HF) from a remaining portion of the byproduct species.

8. The apparatus of claim 7, where the hydrogen fluoride (HF) recovery system further comprises:
a device to convert the solubilized HF into anhydrous HF.

9. The apparatus of claim 8, wherein the fluorine generator further comprises:
one or more electrochemical cells to convert the anhydrous HF to F₂.

10. The apparatus of claim 7, wherein the fluorine generator further comprises:
at least one of a fluidized bed reactor, a rotary calciner, or a reaction vessel to convert the solubilized HF to calcium fluoride (CaF₂); and
a furnace to evolve F₂ from CaF₂.

11. The apparatus of claim 8, wherein the fluorine generator and the vacuum distillation apparatus are disposed adjacent to the process chamber.

12. The apparatus of claim 8, wherein the fluorine generator and the vacuum distillation apparatus are disposed in a location separate from the location of the process chamber.

13. A method for recovering fluorine, comprising:
utilizing a reactive fluorine species in a process performed in a process chamber;
converting fluorine-containing effluents resultant from the process into hydrogen fluoride (HF) and byproduct species within an abatement system coupled to the process chamber;
recovering the HF by separating the HF from the byproduct species in an HF recovery system coupled to the abatement system; and
providing the recovered HF to a fluorine generator to fuel the generation of fluorine (F₂).

14. The method of claim 13, further comprising:
directing the fluorine generated from the fluorine generator to at least one of the process chamber or a second process chamber.

15. The method of claim 13, wherein converting the fluorine-containing effluents into HF and byproduct species, further comprises:
converting the fluorine-containing effluents into HF and the byproduct species by at least one of a thermal oxidation or hydrogenation process.

16. The method of claim 15, wherein recovering the HF further comprises:
dissolving the HF and a soluble portion of the byproduct species in water (H₂O); and
distilling the HF and the soluble portion of the byproduct species to separate the HF from the soluble portion.

17. The method of claim 16, wherein recovering the HF further comprises:
removing H₂O from the distilled HF to form anhydrous HF.

18. The method of claim 16, providing the recovered HF to the fluorine generator further comprising:
reacting the distilled HF with calcium carbonate (CaCO₃) to form calcium fluoride (CaF₂); and
heating the CaF₂ to generate F₂.

19. The method of claim 13, further comprising:
recovering waste hydrogen (H₂) from the fluorine generator; and utilizing the waste hydrogen to covert the fluorine-containing effluents into HF.

20. The method of claim 13, wherein the fluorine-containing effluents comprise at least one of fluorine (F₂), fluorine-containing ions, fluorine-containing radicals, singlet atomic fluorine (F), hydrogen fluoride (HF), silicon tetrafluoride (SiF₄), nitrogen trifluoride (NF₃), or carbon tetrafluoride (CF₄).
